(19) United States
(12) Patent Application Publication
(10) Pub. No.: US 2010/0040984 A1
(43) Pub. Date: Feb. 18, 2010

(54) METHOD OF FABRICATING MICRO ELECTRO-MECHANICAL COMPONENT

(75) Inventors: Young Ho Cho, Daejeon (KR); Yoon Ji Kim, Daegu (KR); Ho Joon Park, Seoul (KR); Young Soo Oh, Seongnam (KR); Hee Ju Son, Suwon (KR); Byeung Gyu Chang, Suwon (KR); Sang Jin Kim, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/350,746

(22) Filed: Jan. 8, 2009

(30) Foreign Application Priority Data
Aug. 12, 2008 (KR) 10-2008-0079004

(51) Int. Cl. G03F 7/20; B23K 1/20; B32B 37/00; C25D 11/02

(52) U.S. Cl. 430/319; 228/176; 156/60; 205/125

(57) ABSTRACT

A method of manufacturing a micro electro-mechanical component having a three-dimensional structure includes preparing a conductive substrate, selectively insulating or removing the conductive substrate to form a functional structure for performing a desired electro-mechanical function, forming a plated structure serving as an electrical connection portion on at least one surface of the functional structure, and mounting the functional structure on a circuit substrate so that the electrical connection portion is connected to a circuit pattern of the circuit substrate.

### CROSS-REFERENCE TO RELATED APPLICATIONS

This application claims the priority of Korean Patent Application No. 2008-0079004 filed on Aug. 12, 2008, in the Korean Intellectual Property Office, the disclosure of which is incorporated herein by reference.

### BACKGROUND OF THE INVENTION

1. Field of the Invention

The present invention relates to a micro electro-mechanical component having a three-dimensional structure, and more particularly, to a method of fabricating a micro electro-mechanical component in which a metal substrate is directly processed to easily form a three-dimensional structure.

2. Description of the Related Art

Examples of micro electro-mechanical components having a three-dimensional structure, which are industrially widely used, includes probes for electrically detecting integrated circuits (ICs) such as a semiconductor and a display, electronic devices such as a switch array and a relay, and optical devices such as a variable optical attenuator.

A method of such a widely used manufacturing the micro electro-mechanical component having the three-dimensional structure includes a multistage electroplating process using a mold formed on a planar substrate or an electroplating process using a mold formed on an etched silicon substrate.

For example, U.S. Pat. No. 6,747,465 discloses the method of manufacturing the micro electro-mechanical component having the three-dimensional structure using the multistage electroplating process using the mold formed on the planar substrate.

A plated bottom electrode is deposited on the planar substrate. A mold is formed on the plated bottom electrode. A conductive material is electroplated on the inside of the mold. The plated bottom electrode deposition, the mold formation, and the electroplating processes are sequentially repeated to manufacture a three-dimensional probe structure. According to this method, since the multistage plated bottom electrode deposition, the mold formation, and the electroplating processes are required, the manufacturing processes are complicated.

In addition, the three-dimensional structure manufactured using only the electroplating process has poor mechanical/electrical characteristics because a plating material itself does not dense in organization. Thus, the three-dimensional structure is not adapted to be used as an electrical connection terminal using the mechanical component.

U.S. Pat. No. 2008-0048687 discloses the method of manufacturing the micro electro-mechanical component having the three-dimensional structure using the electroplating process using the mold formed on the etched silicon substrate.

A silicon substrate is etched to form a recessed portion. A mold is formed on the recessed portion. A conductive material is electroplated on the inside of the mold to manufacture a desired three-dimensional structure. According to this method, since the mold formed on the silicon substrate having the recessed portion is used, the three-dimensional structure may be manufactured without requiring the multistage electroplating process.

However, separate processes in which the silicon substrate is etched to form the recessed portion and the entire silicon substrate is removed after the electroplating process are required. In addition, as described above, the three-dimensional structure manufactured using only the electroplating process has the poor mechanical/electrical characteristics because the plating material itself does not dense in organization.

### SUMMARY OF THE INVENTION

An aspect of the present invention provides a method of manufacturing a micro electro-mechanical component having a three-dimensional structure that has superior mechanical/electrical characteristics and can be realized by a process adapted for mass production.

According to an aspect of the present invention, there is provided a method of manufacturing a micro electro-mechanical component having a three-dimensional structure including: preparing a conductive substrate; selectively insulating or removing the conductive substrate to form a functional structure for performing a desired electro-mechanical function; forming a plated structure serving as an electrical connection portion on at least one surface of the functional structure; and mounting the functional structure on a circuit substrate so that the electrical connection portion is connected to a circuit pattern of the circuit substrate.

According to another aspect of the present invention, there is provided a method of manufacturing a micro electro-mechanical component having a three-dimensional structure including: preparing a conductive substrate; forming a plated structure serving as an electrical connection portion on at least one surface of the conductive substrate; selectively insulating or removing the conductive substrate to form a functional structure for performing a desired electro-mechanical function; and mounting the functional structure on a circuit substrate so that the electrical connection portion is connected to a circuit pattern of the circuit substrate.

The conductive substrate adopted in the present invention may include a metal substrate or a substrate coated with a conductive material.

The forming of the functional structure may be realized by selectively removing the conductive substrate. In this case, one process selected from a mechanical process, a chemical process, and an optical process may be used.

On the other hand, the forming of the functional structure may be realized by selectively electrically insulating the metal substrate. In case where the conductive substrate is a metal substrate, an anodizing process may be performed to selectively insulate the metal substrate.

The forming of the functional structure may further include removing at least portion of a selectively insulated region of the functional structure.

The removing of the selectively insulated region may be performed before the mounting of the functional structure on the circuit substrate, and as occasion demands, the removing of the selectively insulated region may be performed after the mounting of the functional structure on the circuit substrate.

The forming of the plated structure may be realized by forming a mold having an empty space therein using a photolithography process at a position at which a corresponding plated structure is formed and performing a plating process so that the inside of the mold is filled with a conductive filling material.

The method of manufacturing the micro electro-mechanical component may further include forming an additional plated structure on the functional structure or the conductive substrate.

The additional plated structure adopted in the present invention may include a support formed on the same surface as that on which the electrical connection portion is formed and fixed to the circuit substrate to support the functional structure.

The additional plated structure may be formed on a surface opposite to a surface on which the electrical connection portion is formed and provided as a portion of the functional structure.

The forming of the at least one additional plated structure may be realized by forming a mold having an empty space therein using a photolithography process at a position at which a corresponding plated structure is formed and performing a plating process so that the inside of the mold is filled with a conductive filling material.

The circuit substrate may include at least one support formed on a top surface thereof to support the functional structure.

In an embodiment of the present invention, the functional structure may include a functional portion configured to perform a specific electro-mechanical function, a support portion spaced from the functional portion and disposed around the functional portion, at least one connection portion connecting the functional portion to the support portion such that the functional portion is supported by the support portion.

In this case, the electrical connection portion may be formed on the support portion.

On the other hand, in case where at least one of the support portion and the connection portion is selectively insulated or only the functional portion exists, the electrical connection portion may be directly formed on the functional portion.

In some cases, the method of manufacturing the micro electro-mechanical component may further include removing the support portion and the connection portion from the functional structure after the functional structure is mounted on the circuit substrate.

The present invention may be usefully realized in the probe component. In this case, the method of manufacturing the micro electro-mechanical component may further include forming an additional plated structure serving as a probing portion on a surface opposite to a surface on which the electrical connection portion is formed of the functional structure or the conductive substrate.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A to 1E are schematically perspective views illustrating a method of manufacturing a micro electro-mechanical component (probe) according to an embodiment of the present invention;

FIGS. 2A to 2E are schematically perspective views illustrating a method of manufacturing a micro electro-mechanical component (probe) according to another embodiment of the present invention;

FIGS. 3A to 3E are schematically perspective views illustrating a method of manufacturing a micro electro-mechanical component (probe) according to another embodiment of the present invention;

FIGS. 4A to 4E are schematically perspective views illustrating a method of manufacturing a micro electro-mechanical component (probe) according to another embodiment of the present invention;

FIGS. 5A to 5F are schematically perspective views illustrating a method of manufacturing a micro electro-mechanical component (probe) according to another embodiment of the present invention; and

FIGS. 6A to 6E are schematically perspective views illustrating a method of manufacturing a micro electro-mechanical component (probe) according to another embodiment of the present invention.

### DETAILED DESCRIPTION OF THE PREFERRED EMBODIMENT

A term “micro electro-mechanical component” used in the present disclosure includes a three-dimensional structure electrically connecting a specific circuit substrate to a circuit of the specific circuit substrate. The three-dimensional structure refers to a component that interconnects electrical signals between the component and the circuit of the circuit substrate in order to perform a desired electro-mechanical function.

Examples of the three-dimensional structure may includes a probe as well as a switch array or a variable optical attenuator in which the three-dimensional structure is moved due to an electrostatic change to perform a switching function or change quantity of light in a optical path, respectively.

The term “electro-mechanical function” used in the present disclosure includes processes in which a physical or mechanical change occurs due to an electrical or electromagnetic change, or on the other hand, the electrical or electromagnetic change occurs due to the physical or mechanical change and a state in which the physical change and the electrical change occur at the same time during the operation process.

For example, the probe physically contacts with an object to be measured and supplies a voltage supplied from the circuit of the circuit substrate to the object to perform the electro-mechanical function for detecting their changes.

Exemplary embodiments of the present invention will now be described in detail with reference to the accompanying drawings.

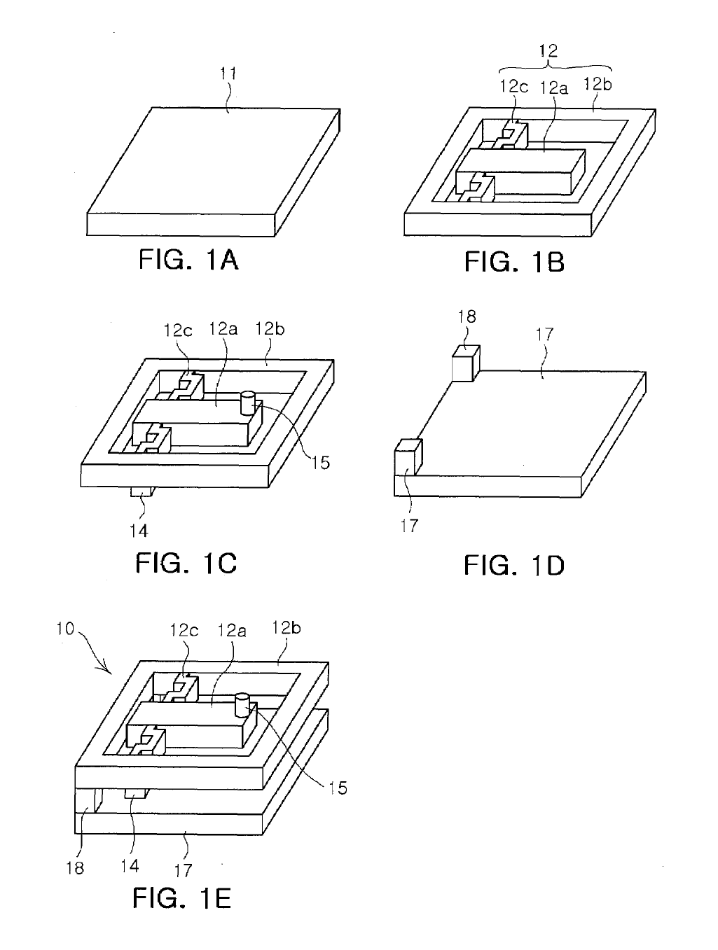

FIGS. 1A to 1E are schematically perspective views illustrating a method of manufacturing a micro electro-mechanical component (probe) according to an embodiment of the present invention. A method of manufacturing a probe is described as an example of this embodiment.

Referring to FIG. 1A, a conductive substrate 11 is prepared. The conductive substrate 11 used in this embodiment may include a substrate formed of only a metal or a substrate plated with a conductive material such as the metal. As described above, since a three-dimensional structure manufactured using the substrate 11 is required to provide an electrical or electromagnetic function, it is required that the substrate 11 used in the present invention may include an electrically conductive component.

In case where a metal substrate is used as the conductive substrate 11, a desired structure may be formed by a selective denaturalization, i.e., selectively insulating the metal substrate using an insulating process such as an anodizing process. An explanation with respect to this processing will be described in detail with reference to the following embodiment.

Referring to FIG. 1B, the conductive substrate 11 is processed to form a functional structure 12 for performing a desired electro-mechanical function.

The functional structure formation process may be largely classified into a selectively electrical insulating process and a selective removing process. In this embodiment, the selective removing process will be described as an example. The selective removing process may include a mechanical process, a chemical process, or an optical process (e.g., a laser process) that is a well-known process. The substrate 11 is patterned using the selective removing process to form the functional structure 12 having the desired electro-mechanical function.

The functional structure 12 includes a functional portion 12a configured to perform a specific electro-mechanical function, a support portion 12b spaced from the functional portion 12a and disposed around the functional portion 12a, two connection portions 12c connecting the functional portion 12a to the support portion 12b such that the functional portion 12a is supported by the support portion 12b.

Referring to FIG. 1C, plated structures 14 and 15 are formed on a top surface and a bottom surface of the functional structure 12 using a plating process.

The plated structure 14 formed on the bottom surface of the functional structure 12 serves as an electrical connection portion. The electrical connection portion electrically connects the functional portion 12a of the functional structure 12 to a circuit of a circuit substrate (reference numeral 17 of FIG. 1D) used as a mechanical part in a subsequent process.

As described in this embodiment, in case where the functional portion 12a, the connection portion 12c, and the support portion 12b are formed of a conductive material, the functional portion 12a and the connection portion 12c may be formed on a bottom surface of the support portion 12b. Of course, as occasion demands, the connection portion 12c and the support portion 12b may be directly formed on the functional portion 12a.

As described above, the probe component is described in this embodiment as an example. Thus, an additional plated structure 15 is formed on a top surface of the functional portion 12a, i.e., a surface opposite to a surface on which the electrical connection portion 14 is formed in order to provide a probing portion required for the probe.

In a formation method of the plated structures 14 and 15 adopted in the present invention, molds having empty spaces therein (hereinafter, referred to as “empty molds”) are formed using a photolithography process at positions at which the corresponding plated structures are formed. The plating process is performed to fill the insides of the empty molds using a conductive filling material. Therefore, the plated structures 14 and 15 are formed.

Referring to FIG. 1D, the circuit substrate 17 is prepared. The circuit substrate 17 includes a predetermined circuit. As described above, the circuit of the circuit substrate 17 is electrically connected to the functional structure 12 through the electrical connection portion 14.

A support structure 18 for stably supporting the functional structure 12 may be formed on the circuit substrate 17. The support structure 18 may not be required to be formed of a conductive material, and may be formed of a resin material having stable mechanical properties and improved adhesion.

Referring to FIG. 1E, the functional structure 12 is mounted on the circuit substrate 17.

In the mounting process, the electrical connection portion 14 is connected to the circuit of the circuit substrate 12, and this connection is performed using a typical solder bonding process or thermal pressing process.

The functional structure 12 may be supported somewhat by the electrical connection portion 14 and further stably supported by the support structure 18. The mounting process is realized using the following process. A portion of the support structure 18 is formed of an adhesive resin to attach the adhesive resin using the thermal pressing process or an ultrasonic process.

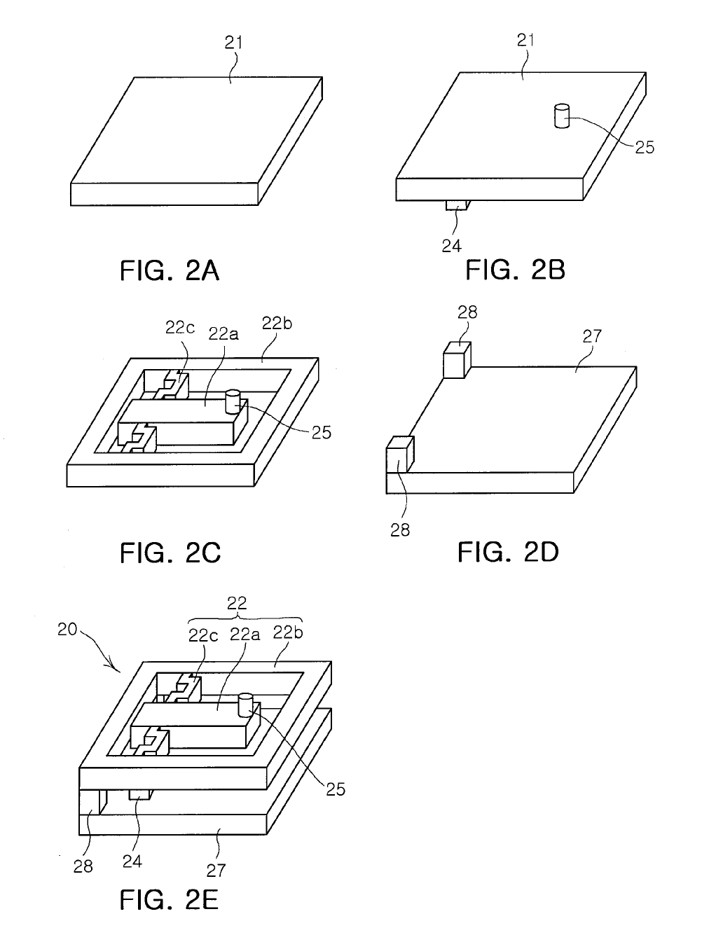

The embodiment of FIG. 1 may be modified in various ways. The order of the steps of the present invention may be changed. In the preceding embodiment, although the plated structure formation process is performed after the functional structure formation process, the present invention is not limited thereto. For example, the plated structure formation process may be performed before the functional structure formation process, i.e., directly performed on the conductive substrate. These processes are described in FIGS. 2A to 2E.

FIGS. 2A to 2E are schematically perspective views illustrating a method of manufacturing a micro electro-mechanical component (probe) according to another embodiment of the present invention.

Referring to FIG. 2A, a conductive substrate 21 is prepared. The conductive substrate 21 used in this embodiment may include a substrate formed of only a metal or a substrate plated with a conductive material such as the metal.

Referring to FIG. 2B, plated structures 24 and 25 are formed on a top surface and a bottom surface of the conductive substrate 21 using a plating process.

The plated structure 24 serves as an electrical connection portion. The plated structure 25 formed on the surface opposite to the surface on which the plated structure 24 is formed is a structure for providing a probing portion required for a probe. The electrical connection portion 24 and the probing portion 25 correspond to the electrical connection portion 14 and the probing portion 15 described in FIG. 1C, respectively.

Referring to FIG. 2C, the conductive substrate 21 is processed to form a functional structure 22 for performing a desired electro-mechanical function.

In this embodiment, a selective removing process may include a mechanical process, a chemical process, or an optical process that is a well-known process.

In this embodiment, similar to the embodiment of FIG. 1, the functional structure 22 includes a functional portion 22a configured to perform a specific electro-mechanical function, a support portion 22b spaced from the functional portion 22a and disposed around the functional portion 22a, two connection portions 22c connecting the functional portion 22a to the support portion 22b such that the functional portion 22a is supported by the support portion 22b.

Referring to FIG. 2D, a circuit substrate 27 is prepared. The circuit substrate 27 may include a ceramic substrate having an interlayer circuit by a conductive via and a conductive pattern or well known various circuit substrates such as a printed circuit board (PCB). A support structure 28 is stably supporting the functional structure 22 is formed on the circuit substrate 27.

Referring to FIG. 2E, the functional structure 22 is mounted on the circuit substrate 27.

In the mounting process, the electrical connection portion 24 maybe connected to a circuit of the circuit substrate 27. The functional structure 22 may be stably supported to the circuit substrate 27 due to the electrical connection portion 24 and the support structure 28.

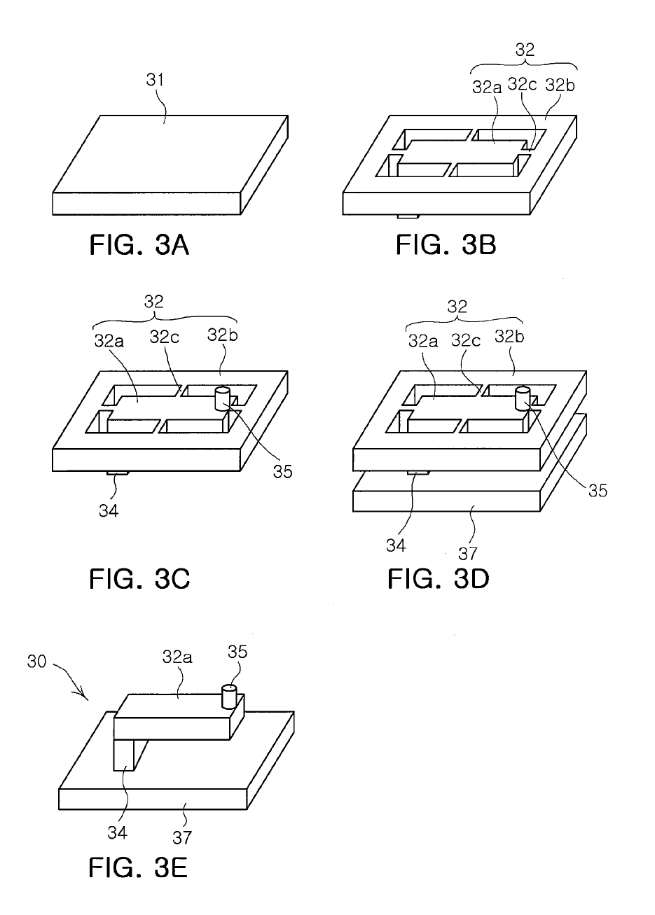

In the preceding embodiment, although the functional structure includes the functional portion, the support portion, and the connection portion connecting the functional portion to the support portion, the functional structure adoptable in the present invention may be changed into various shapes. That is, the functional structure may be realized with various modified embodiments in case where the functional structure satisfyingly performs the specific electro-mechanical function. In implementation of the same probe as the preceding embodiment, a method of manufacturing a probe having a further simple structure will be described in FIG. 3.

FIGS. 3A to 3E are schematically perspective views illustrating a method of manufacturing a micro electro-mechanical component (probe) according to another embodiment of the present invention.

Referring to FIG. 3A, a conductive substrate 31 is prepared. The conductive substrate 31 may include a metal substrate or an electrically insulative substrate plated with a conductive material.

Referring to FIG. 3B, the conductive substrate 31 is processed to form a primary functional structure 32 for performing a desired electro-mechanical function.

In this embodiment, similar to the preceding embodiment, the primary functional structure 32 includes a functional portion 32a configured to perform a specific electro-mechanical function, a support portion 32b spaced from the functional portion 32a and disposed around the functional portion 32a, four connection portions 32c connecting the functional portion 32a to the support portion 32b. However, unlike the preceding embodiment, the support portion 32b and the connection portion 32c except the functional portion 32a are maintained only during processing. That is, the support portion 32b and the connection portion 32c are provided for easily treating the functional portion 32a that is a final functional structure, and then are removed in a final process (FIG. 3G).

Referring to FIG. 3C, plated structures 34 and 35 are formed on a top surface and a bottom surface of the primary functional structure 32 using a plating process.

The plated structure 34 formed on the bottom surface of the primary functional structure 32 serves as an electrical connection portion. However, since the connection portion 32c and the support portion 32c except the function portion 32a are removed all in a subsequent process, the electrical connection portion 34 is required to be formed on a bottom surface of the functional portion 32a. Also, the additional plated structure 35 is formed on a top surface of the functional portion 32a in order to provide a probing portion required for a probe.

Referring to FIG. 3D, a circuit substrate 37 is prepared. The circuit substrate 37 includes a predetermined circuit. As described above, the circuit of the circuit substrate 37 is electrically connected to the functional structure 32 through the electrical connection portion 34.

Referring to FIG. 3E, the functional structure 32 is mounted on the circuit substrate 37.

In this mounting process, the electrical connection portion 34 is connected to the circuit of the circuit substrate 32, and this connection is performed using a typical solder bonding process or thermal pressing process. In this embodiment, since an additional support structure is not provided, the electrical connection portion 32a performs an electrical connection function and a mechanical support function together.

In the above-described embodiments, although the functional structure formation process is performed using a selective removing process, the present invention is not limited thereto. For example, a selectively electrical insulating process in addition to the selective removing process may be used in the functional structure formation process.

In the selectively electrical insulating process adopted in the present invention, a partial region of the conductive substrate is selectively denaturalized, i.e., patterned using an insulating process to form a structure having a desired electro-mechanical function.

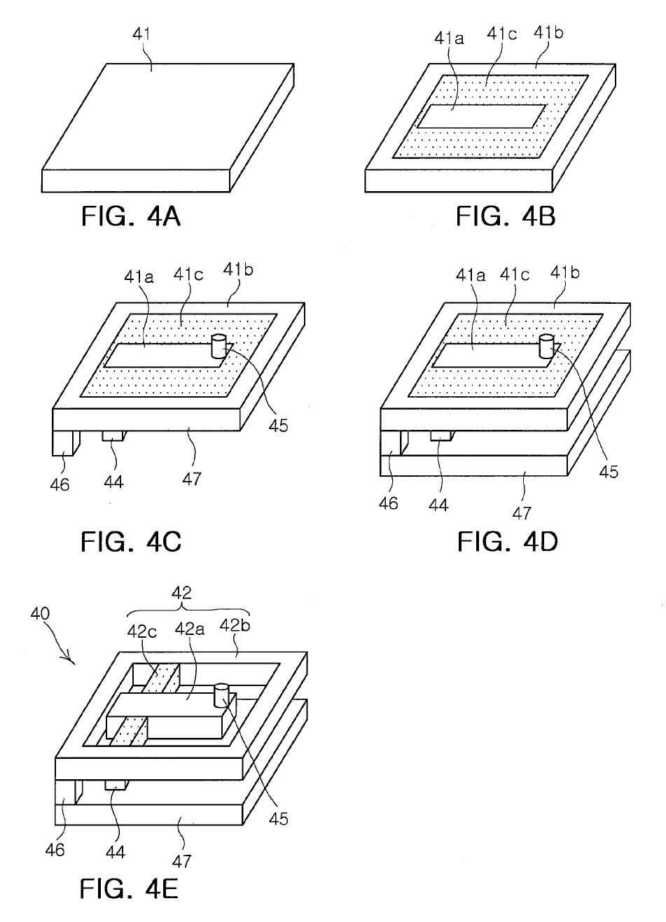

The selectively electrical insulating process may be partially combined with the selective removing process such as an etch process in order to form a complete functional structure. In embodiments of FIGS. 4 to 6, a manufacturing method adopting the functional structure formation process using the selectively electrical insulating process will be described.

Referring to FIG. 4A, a metal substrate 41 is prepared. The metal substrate 41 may be used in this embodiment such that a desired structure is formed by selectively insulating the metal substrate 41 using an insulating process such as a selective denaturalization process, i.e., an anodizing process.

Referring to FIG. 4B, a region of the metal substrate 41 required for manufacturing a functional structure using the anodizing process is selectively denaturalized.

In this embodiment, a region between an inner region 41a corresponding to a functional portion configured to perform a specific electro-mechanical function and an outer region 41b in which a support portion is formed, that is, the region except the inner region 41a and the outer region 41b is anodized.

Referring to FIG. 4C, plated structures 44, 45, and 46 are formed on a top surface and a bottom surface of the metal substrate 41 using a plating process.

The plated structure 44 formed on a bottom surface of the inner region 41a serves as an electrical connection portion. The plated structure 45 formed on a top surface of the inner region 41a serves as a probing portion for a probe. In this embodiment, the plated structure is additionally formed on a bottom surface of the outer region. The plated structure formed on the bottom surface of the outer region serves as a support. In this case, it does not matter that an auxiliary support is not formed on the circuit substrate.

In the above-described plated structures 44, 45, and 46, empty molds are formed using a photolithography process at positions at which the corresponding plated structures are formed. The plating process is performed to fill the insides of the empty molds using a conductive filling material. The plurality of plated structures 44, 45, and 46 may be achieved at the same time through a batch process. Of course, the plating process may be performed on the metal substrate 41 before an anodizing process is performed.

Referring to FIG. 4D, a circuit substrate 47 is prepared. The circuit substrate 47 includes a predetermined circuit. The circuit of the circuit substrate 47 is electrically connected to the electrical connection portion 44 of the anodized metal substrate 41. Also, the plated structure 46 that is the support is attached to the circuit substrate 47. This process may be performed using a typical solder bonding process, a thermal pressing process, or an ultrasonic process.

Referring to FIG. 4E, an anodized region of the anodized metal substrate 41 is partially removed to provide the desired final functional structure 42. The removing process is easily realized with an etchant. Furthermore, the anodized region is partially etched to form two connection portions 42c, thereby providing the functional structure 42, similar to the functional structure 12 as described in FIG. 1, including a functional portion 42a configured to perform a specific electro-mechanical function, a support portion 42b, and a connection portion 42c connecting therebetween.

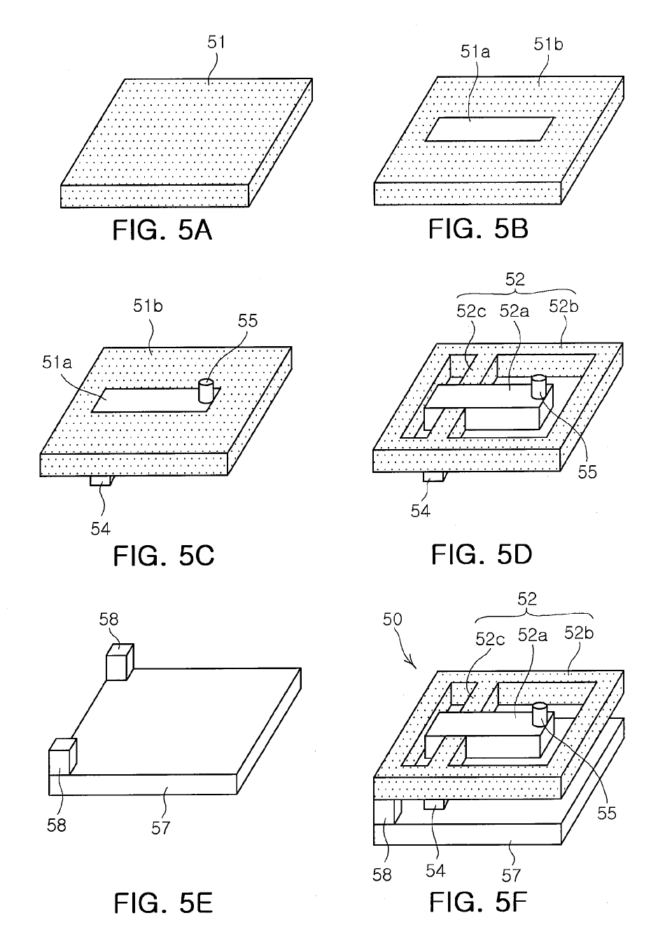

FIGS. 5A to 5F are schematically perspective views illustrating a method of manufacturing a micro electro-mechanical component (probe) according to another embodiment of the present invention.

Referring to FIG. 5A, this manufacturing method starts by preparing a metal substrate 51.

Referring to FIG. 5B, a partial region of the metal substrate 51 is selectively anodized as a primary process for manufacturing a functional structure. In this embodiment, an entire outer region 51b except for an inner region 51a corresponding to a functional portion configured to perform a specific electro-mechanical function is oxidized.

Referring to FIG. 5c, plated structures 54 and 55 are formed on a top surface and a bottom surface of the substrate 51 using a plating process.

The plated structure 54 formed on a bottom surface of the inner region 51a serves as an electrical connection portion. The plated structure 55 formed on a top surface of the inner region 51a serves as a probing portion for a probe. Of course, the plating process may be performed on the metal substrate 51 before an anodizing process is performed.

Referring to FIG. 5D, an anodized region of the anodized metal substrate 51 is partially removed to provide the desired final functional structure 52.

That is, the anodized outer region 51b is partially etched to form two connection portions 42c, thereby providing the functional structure 52, similar to the functional structure 12 as described in FIG. 1, including a functional portion 52a configured to perform a specific electro-mechanical function, a support portion 52b, and a connection portion 52c connecting therebetween.

Referring to FIG. 5E, a circuit substrate 57 is prepared. The circuit substrate 57 includes a predetermined circuit. A support 58 for stably supporting the functional structure 52 may be formed on the circuit substrate 57.

Referring to FIG. 5F, the circuit of the circuit substrate 57 is electrically connected to the electrical connection portion 54 of the functional structure 52. This process may be performed using a typical solder bonding process, a thermal pressing process, or an ultrasonic process.

Unlike the embodiment of FIG. 4, in this embodiment, the anodizing process is performed, and then, the selective etch process is performed before the functional structure 52 is mounted on the circuit substrate to a desired final functional structure. On the other hand, like the embodiment of FIG. 4, the selective etch process may be performed in a state that the functional structure 52 is mounted on the circuit substrate to form the desired final functional structure.

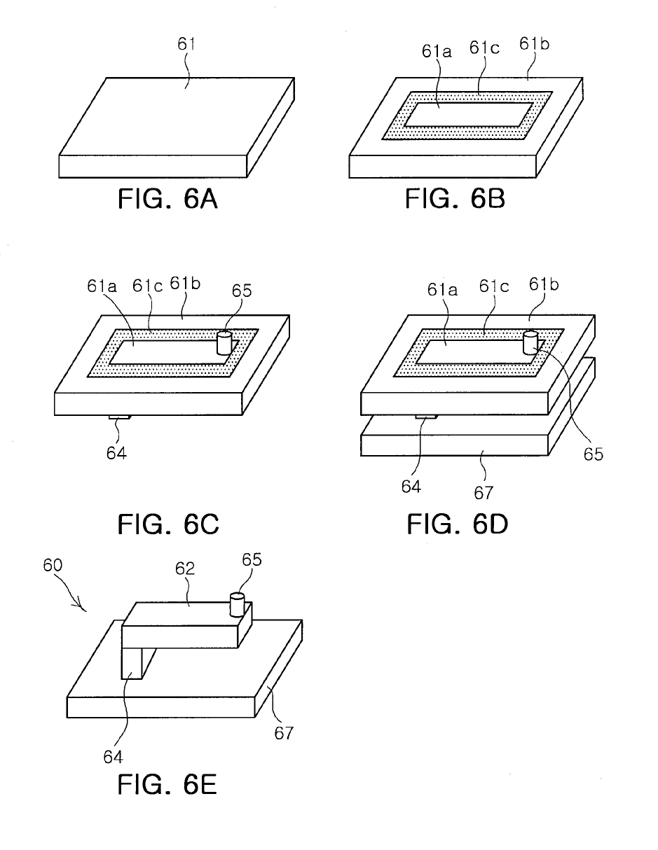

FIGS. 6A to GE are schematically perspective views illustrating a method of manufacturing a micro electro-mechanical component (probe) according to another embodiment of the present invention.

Referring to FIG. 6A, this manufacturing method starts by preparing a metal substrate 61.

Referring to FIG. 6B, a region of the metal substrate 61 required for manufacturing a functional structure using an anodizing process is selectively denaturalized. In this embodiment, a region between an inner region 61a corresponding to a functional portion configured to perform a specific electro-mechanical function and an outer region 61b in which a support portion is formed, i.e., the region except the inner region 61a and the outer region 61b is anodized.

Referring to FIG. 6C, plated structures 64 and 65 are formed on a top surface and a bottom surface of the substrate 61 using a plating process.

The plated structure 64 formed on a bottom surface of the inner region 61a serves as an electrical connection portion. The plated structure 65 formed on a top surface of the inner region 61a serves as a probing portion for a probe.

Referring to FIG. 6D, the anodized substrate 61 is mounted on the circuit substrate 67.

The circuit substrate 67 includes a predetermined circuit. As described above, the circuit of the circuit substrate 67 is electrically connected to the electrical connection portion 64 of the anodized substrate 61. This process may be performed using a typical solder bonding process, a thermal pressing process, or an ultrasonic process.

Referring to FIG. 6E, an anodized region of the anodized metal substrate 61 is partially removed to provide the desired final functional structure 62.

The anodized region is completely etched and removed to remove the entire portion remaining except the functional structure 62 configured to perform a specific electro-mechanical function. The functional structure 62 illustrated in FIG. 6E is similar to the probe shape described in FIG. 3.

As described above, although the probe shape is described as an example, the present invention is not limited thereto. For example, the present invention may be usefully applied to the micro electro-mechanical component in which the three-dimensional structure is formed on the specific circuit substrate to perform the electro-mechanical function and electrically connect the structure to the circuit of the circuit substrate.

As described above, according to the present invention, the conductive substrate is manufactured into a basic shape having the three-dimensional structure by directly applying the well-known process such as the mechanical process, the chemical process, or the optical process, and then, additional plating process is performed to easily manufacture the micro electro-mechanical component of the three-dimensional structure having the improved mechanical/electrical characteristics with high yield.

Also, when the required structure such as the electrical connection portion is formed, since the plating process is directly performed on the conductive substrate such as the metal substrate, it does not need to perform a seed layer formation process for plating.

Since the conductive substrate such as the metal substrate has predetermined elasticity, resiliency due to an elastic effect can be improved during the mechanical operation. In addition, in case where the functional structure is realized with a structure including the functional portion, the support portion, and the connection portion connecting therebetween, the mechanical operation of the functional portion can be further improved.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing a micro electro-mechanical component having a three-dimensional structure, the method comprising:
preparing a conductive substrate;
selectively insulating or removing the conductive substrate to form a functional structure for performing a desired electro-mechanical function;
forming a plated structure serving as an electrical connection portion on at least one surface of the functional structure; and
mounting the functional structure on a circuit substrate so that the electrical connection portion is connected to a circuit pattern of the circuit substrate.

2. The method of claim 1, wherein the conductive substrate comprises a metal substrate or a substrate coated with a conductive material.

3. The method of claim 1, wherein the forming of the functional structure comprises selectively removing the conductive substrate using one process of mechanical process, a chemical process, and an optical process.

4. The method of claim 1, wherein the conductive substrate comprises a metal substrate, and the forming of the functional structure comprises selectively electrically insulating the metal substrate using an anodizing process.

5. The method of claim 4, wherein the forming of the functional structure further comprises removing at least portion of a selectively insulated region of the functional structure.

6. The method of claim 5, wherein the removing of the selectively insulated region is performed before the mounting of the functional structure on the circuit substrate.

7. The method of claim 5, wherein the removing of the selectively insulated region is performed after the mounting of the functional structure on the circuit substrate.

8. The method of claim 1, wherein the forming of the plated structure comprises forming a mold having an empty space therein using a photolithography process at a position at which a corresponding plated structure is formed and performing a plating process so that the inside of the mold is filled with a conductive filling material.

9. The method of claim 1, further comprising forming an additional plated structure on the functional structure or the conductive substrate.

10. The method of claim 9, wherein the additional plated structure comprises a support formed on the same surface as that on which the electrical connection portion is formed and fixed to the circuit substrate to support the functional structure.

11. The method of claim 9, wherein the additional plated structure is formed on a surface opposite to a surface on which the electrical connection portion is formed and provided as a portion of the functional structure.

12. The method of claim 9, wherein the forming of the at least one additional plated structure comprises forming a mold having an empty space therein using a photolithography process at a position at which a corresponding plated structure is formed and performing a plating process so that the inside of the mold is filled with a conductive filling material.

13. The method of claim 1, wherein the circuit substrate comprises at least one support formed on a top surface thereof to support the functional structure.

14. The method of claim 1, wherein the forming of the functional structure comprises a functional structure comprising a functional portion configured to perform a specific electro-mechanical function, a support portion spaced from the functional portion and disposed around the functional portion, at least one connection portion connecting the functional portion to the support portion such that the functional portion is supported by the support portion.

15. The method of claim 14, wherein the electrical connection portion is formed on the support portion.

16. The method of claim 14, wherein the conductive substrate comprises a metal substrate, and
the forming of the functional structure comprises selectively electrically insulating the metal substrate using an anodizing process and removing at least portion of a selectively insulated region of the functional structure,
wherein at least one of the support portion and the connection portion is selectively insulated.

17. The method of claim 16, wherein the electrical connection portion is formed on the functional portion.

18. The method of claim 17, after the functional structure is mounted on the circuit substrate, further comprising removing the support portion and the connection portion from the functional structure.

19. The method of claim 1, wherein the micro electro-mechanical component comprises a probe component, and
further comprising forming an additional plated structure serving as a probe tip on a surface opposite to a surface on which the electrical connection portion is formed of the functional structure or the conductive substrate.

20. A method of manufacturing a micro electro-mechanical component having a three-dimensional structure, the method comprising:
preparing a conductive substrate;
forming a plated structure serving as an electrical connection portion on at least one surface of the conductive substrate;
selectively insulating or removing the conductive substrate to form a functional structure for performing a desired electro-mechanical function; and
mounting the functional structure on a circuit substrate so that the electrical connection portion is connected to a circuit pattern of the circuit substrate.

21. The method of claim 20, wherein the conductive substrate comprises a metal substrate or a substrate coated with a conductive material.

22. The method of claim 20, wherein the forming of the functional structure comprises selectively removing the conductive substrate using one process of a mechanical process, a chemical process, and an optical process.

23. The method of claim 20, wherein the conductive substrate comprises a metal substrate, and the forming of the functional structure comprises selectively electrically insulating the metal substrate using an anodizing process.

24. The method of claim 23, wherein the forming of the functional structure further comprises removing at least portion of a selectively insulated region of the functional structure.

25. The method of claim 24, wherein the removing of the selectively insulated region is performed before the mounting of the functional structure on the circuit substrate.

26. The method of claim 24, wherein the removing of the selectively insulated region is performed after the mounting of the functional structure on the circuit substrate.

27. The method of claim 20, wherein the forming of the plated structure comprises forming a mold having an empty space therein using a photolithography process at a position at which a corresponding plated structure is formed and performing a plating process so that the inside of the mold is filled with a conductive filling material.

28. The method of claim 20, further comprising forming an additional plated structure on the functional structure or the conductive substrate.

29. The method of claim 28, wherein the additional plated structure comprises a support formed on the same surface as that on which the electrical connection portion is formed and fixed to the circuit substrate to support the functional structure.

30. The method of claim 28, wherein the additional plated structure is formed on a surface opposite to a surface on which the electrical connection portion is formed and provided as a portion of the functional structure.

31. The method of claim 28, wherein the forming of the at least one additional plated structure comprises forming a mold having an empty space therein using a photolithography process at a position at which a corresponding plated structure is formed and performing a plating process so that the inside of the mold is filled with a conductive filling material.

32. The method of claim 20, wherein the circuit substrate comprises at least one support formed on a top surface thereof to support the functional structure.

33. The method of claim 20, wherein the forming of the functional structure comprises a functional structure comprising a functional portion configured to perform a specific electro-mechanical function, a support portion spaced from the functional portion and disposed around the functional portion, at least one connection portion connecting the functional portion to the support portion such that the functional portion is supported by the support portion.

34. The method of claim 33, wherein the electrical connection portion is formed on the support portion.

35. The method of claim 33, wherein the conductive substrate comprises a metal substrate, and
the forming of the functional structure comprises selectively electrically insulating the metal substrate using an anodizing process and removing at least portion of a selectively insulated region of the functional structure,
wherein at least one of the support portion and the connection portion is selectively insulated.

36. The method of claim 35, wherein the electrical connection portion is formed on the functional portion.

37. The method of claim 36, after the functional structure is mounted on the circuit substrate, further comprising removing the support portion and the connection portion from the functional structure.

38. The method of claim 20, wherein the micro electro-mechanical component comprises a probe component, and
further comprising forming an additional plated structure serving as a probe tip on a surface opposite to a surface on which the electrical connection portion is formed of the functional structure or the conductive substrate.
